(19) United States
(12) Patent Application Publication
(10) Pub. No.: US 2026/0047494 A1
(43) Pub. Date: Feb. 12, 2026

(54) SEMICONDUCTOR MODULE ARRANGEMENT

(71) Applicant: Infineon Technologies AG, Neubiberg (DE)

(72) Inventors: Thomas Raker, Geseke (DE); Andressa Colvero Schittler, Ense (DE)

(21) Appl. No.: 19/283,976

(22) Filed: Jul. 29, 2025

(30) Foreign Application Priority Data
Aug. 12, 2024 (DE) 102024207658.9

(51) Int. Cl. H01L 25/07; H01L 23/00; H01L 23/482

(52) U.S. Cl. CPC H01L 25/072; H01L 23/482; H01L 24/48; H01L 2224/48137; H01L 2224/48227

(57) ABSTRACT

A semiconductor module arrangement includes a first substrate having a dielectric insulation layer and a first metallization layer arranged on a surface of the dielectric insulation layer. The first metallization layer includes first, second, third, and fourth sections. The semiconductor module arrangement further includes two or more controllable semiconductor elements each including first, second, and third contact pads. The second contact pad of each controllable semiconductor element is electrically coupled to the first section. The first contact pad of each controllable semiconductor element is electrically coupled to the second section by one or more electrical connection elements. The third contact pad of each controllable semiconductor element is electrically coupled to the third section by one or more electrical connection elements. The first contact pad of each controllable semiconductor element is electrically coupled to the fourth section by one or more electrical connection elements.

### TECHNICAL FIELD

The instant disclosure relates to semiconductor module arrangements.

### BACKGROUND

Power semiconductor module arrangements often include at least one semiconductor substrate arranged in a housing. A semiconductor arrangement including a plurality of controllable semiconductor elements (e.g., IGBTs, MOSFETs, HEMTs, etc.) is arranged on each of the at least one substrate. Each substrate usually comprises a substrate layer (e.g., a ceramic layer), a first metallization layer deposited on a first side of the substrate layer, and, optionally, a second metallization layer deposited on a second side of the substrate layer. The controllable semiconductor elements are mounted, for example, on the first metallization layer. The second metallization layer may optionally be attached to a base plate or heat sink. In many applications, two or more individual controllable semiconductor elements are electrically coupled in parallel to each other in order to fulfill requirements concerning a current capability of the arrangement. However, when controllable semiconductor elements that are electrically coupled in parallel are switched on and off, oscillations may occur. One type of oscillation that may occur are so-called inter-chip oscillations, where the parasitic capacitances of the controllable semiconductor elements oscillate against parasitic inductances that are present between the respective controllable semiconductor elements. Such oscillations may cause EMI (electromagnetic interference) problems and/or unwanted voltage spikes that can cause damage to the chip gate oxide.

Hence, there is a general need for a semiconductor module arrangement in which oscillations, and in particular inter-chip oscillations, are significantly reduced.

### SUMMARY

A semiconductor module arrangement includes a first substrate including a dielectric insulation layer and a first metallization layer arranged on a surface of the dielectric insulation layer, wherein the first metallization layer includes a first section, a second section, a third section, and a fourth section, two or more controllable semiconductor elements, each controllable semiconductor element of the two or more controllable semiconductor elements including a first contact pad, a second contact pad, and a third contact pad, wherein the second contact pads of the two or more controllable semiconductor elements are electrically coupled to the first section, the first contact pad of each controllable semiconductor element of the two or more controllable semiconductor elements is electrically coupled to the second section by means of one or more electrical connection elements, the third contact pad of each controllable semiconductor element of the two or more controllable semiconductor elements is electrically coupled to the third section by means of one or more electrical connection elements, and the first contact pad of each controllable semiconductor element of the two or more controllable semiconductor elements is electrically coupled to the fourth section by means of one or more electrical connection elements.

The invention may be better understood with reference to the following drawings and the description. The components in the figures are not necessarily to scale, emphasis instead being placed upon illustrating the principles of the invention. In the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 schematically illustrates a top view of a conventional semiconductor module arrangement.

FIG. 3 is a circuit diagram of a half-bridge arrangement.

FIG. 4 schematically illustrates a top view of a semiconductor module arrangement according to embodiments of the disclosure.

FIG. 5 schematically illustrates a top view of a semiconductor module arrangement according to further embodiments of the disclosure.

FIG. 6 is a three-dimensional view of a section of the semiconductor module arrangement of FIG. 5.

FIG. 7 schematically illustrates a top view of a semiconductor module arrangement according to even further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element, or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connecting pads and includes at least one semiconductor element with electrodes. The pads are electrically connected to the electrodes which includes that the pads are the electrodes and vice versa.

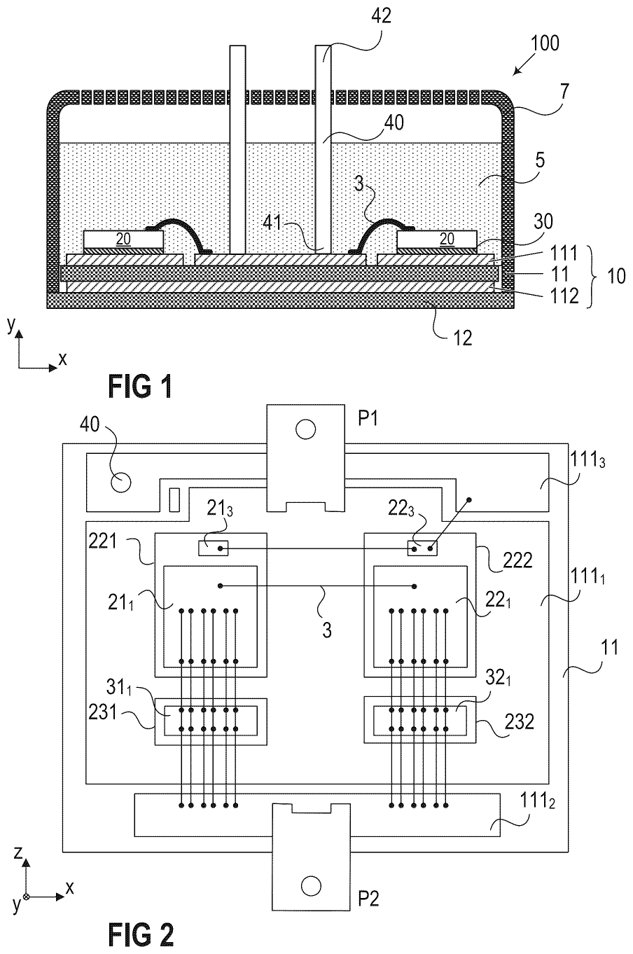

Referring to FIG. 1, a cross-sectional view of a semiconductor module arrangement 100 is schematically illustrated. The semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 12 which forms a base surface of the housing 7, while the housing 7 itself solely comprises sidewalls and a cover. This, however, is only an example. It is also possible that the housing 7 further comprises a base surface, and the substrate 10 and the base plate 12 be arranged inside the housing 7 and on the base surface of the housing 7. In some power semiconductor module arrangements 100, more than one substrate 10 is arranged on a single base plate 12 or on the base surface of a housing 7. According to another example, the base plate 12 is omitted and the substrate 10 itself forms a base surface of the housing 7.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), and/or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes three different sections. This, however, is only an example. Any other number of sections is possible. Different semiconductor bodies 20 may be mounted to the same or to different sections of the first metallization layer 111. Different sections of the first metallization layer 111 may have no electrical connection or may be electrically connected to one or more other sections using electrical connections 3 such as, e.g., bonding wires. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer 30 may be a solder layer, a layer of an electrically conductive adhesive, or a layer of a sintered metal powder, e.g., a sintered silver powder, for example. According to other examples, it is also possible that the second metallization layer 112 is a structured layer. It is further possible to omit the second metallization layer 112 altogether.

The power semiconductor module arrangement 100 further includes terminal elements 4. Only two terminal elements 4 are schematically illustrated in FIG. 1. A power semiconductor module arrangement 100, however, generally may include only one, or more than two terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of each of the terminal elements 4 protrudes out of the housing 7. The terminal elements 4 may be electrically contacted from the outside at their respective second ends 42. A first part of the terminal elements 4 may extend through the inside of the housing 7 in a vertical direction y. The vertical direction y is a direction perpendicular to a top surface of the substrate 10, wherein the top surface of the substrate 10 is a surface on which at least one semiconductor body 20 is mounted. The terminal elements 4 illustrated in FIG. 1, however, are only an example. Terminal elements 4 may be implemented in any other way and may be arranged anywhere within the housing 7. For example, one or more terminal elements 4 may be arranged close to or adjacent to the sidewalls of the housing 7. Terminal elements 4 could also protrude through the sidewalls of the housing 7 instead of through the cover. The first end 41 of a terminal element 4 may be electrically and mechanically connected to the substrate 10 by an electrically conductive connection layer, for example (not explicitly illustrated for the terminal elements 4 in FIG. 1). Such an electrically conductive connection layer may be a solder layer, a layer of an electrically conductive adhesive, or a layer of a sintered metal powder, e.g., a sintered silver (Ag) powder, for example. The first end 41 of a terminal element 4 may also be electrically coupled to the substrate 10 via one or more electrical connections 3, for example. The second ends 42 of the terminal elements 4 may optionally be connected to a printed circuit board, for example (not illustrated in FIG. 1).

With further reference to FIG. 1, the semiconductor module arrangement 100 may further include an encapsulant 5. The encapsulant 5 may consist of or include a silicone gel or may be a rigid molding compound, for example. The encapsulant 5 may at least partly fill the interior of the housing 7, thereby covering the components and electrical connections that are arranged on the substrate 10. The terminal elements 4 may be partly embedded in the encapsulant 5. At least their second ends 42, however, are not covered by the encapsulant 5 and protrude from the encapsulant 5 through the housing 7 to the outside of the housing 7. The encapsulant 5 is configured to protect the components and electrical connections of the semiconductor module arrangement 100, in particular the components arranged on the substrate 10 and inside the housing 7, from certain environmental conditions and mechanical damage.

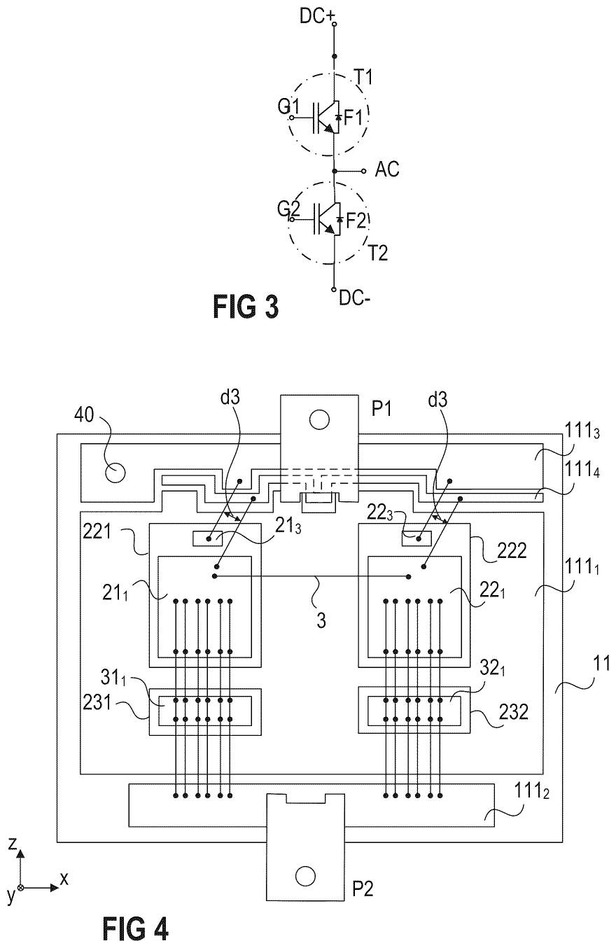

As has been described above, the semiconductor bodies 20 arranged on the substrate 10 may form a semiconductor arrangement. According to one example, the semiconductor bodies 20 may form a half-bridge arrangement. A circuit diagram of a half-bridge arrangement is schematically illustrated in FIG. 3. A half-bridge arrangement generally comprises two controllable semiconductor elements T1, T2 arranged in series between a first terminal and a second terminal. The first terminal may be electrically coupled to a first electrical potential (e.g., positive potential, DC+), and the second terminal may be electrically coupled to a second electrical potential (e.g., negative potential, DC−) that is different from the first electrical potential. A common node between the two controllable semiconductor elements T1, T2 is generally connected to or forms an output node, AC. If, like in the present example, the first and second controllable semiconductor elements are IGBTs, a first freewheeling element F1 is coupled in parallel to the first controllable semiconductor element T1, and a second freewheeling element F2 is coupled in parallel to the second controllable semiconductor element T2. If the controllable semiconductor elements are, for example, SiC MOSFETs no separate freewheeling element is required. In a semiconductor module arrangement according to the present example, each of the first controllable semiconductor element T1, the second controllable semiconductor element T2, the first freewheeling element F1, and the second freewheeling element F2 may be implemented by means of two or more semiconductor bodies 20. For example, the first controllable semiconductor element T1 as illustrated in FIG. 3 may be implemented by means of two or more semiconductor bodies 20, each semiconductor body 20 comprising a controllable semiconductor element 22x. The two or more controllable semiconductor elements 22x are coupled in parallel to form the first controllable semiconductor element T1. In the half-bridge arrangement illustrated in FIG. 3, the first controllable semiconductor element T1 is often referred to as high-side driver/switch, and the second controllable semiconductor element T2 is often referred to as low-side driver/switch. It is noted that the half-bridge arrangement as exemplarily illustrated in FIG. 3 is only an example. Semiconductor elements may generally be similarly arranged in any other kind of semiconductor arrangement.

Now referring to FIG. 2, a top view of a semiconductor module arrangement is schematically illustrated. The semiconductor module arrangement comprises a substrate 10 comprising a dielectric insulation layer 11 and a first metallization layer 111 arranged on a surface of the dielectric insulation layer 11, wherein the first metallization layer 111 comprises a first section 111₁, a second section 111₂, and a third section 111₃. The semiconductor arrangement further comprises two controllable semiconductor elements 221, 222, each controllable semiconductor element 221, 222 of the two controllable semiconductor elements 221, 222 comprising a first contact pad 21₁, 22₁, a second contact pad, and a third contact pad 21₃, 22₃. The semiconductor module arrangement further comprises two freewheeling elements 231, 232, each freewheeling element 231, 232 of the two freewheeling elements 231, 232 comprising a first contact pad 31₁, 32₁, and a second contact pad. The second contact pads of the two controllable semiconductor elements 221, 222 and the second contact pads of the two or more freewheeling elements 231, 232 are electrically coupled to the first section 111₁. In the arrangement illustrated in FIG. 2, the controllable semiconductor elements 221, 222 and the freewheeling elements 231, 232 are implemented as so-called vertical devices, and the second contact pads of the two controllable semiconductor elements 221, 222 and the second contact pads of the two or more freewheeling elements 231, 232 are electrically coupled to the first section 111₁ by means of electrically conductive connection layers and are therefore not visible in the top view of FIG. 2. Implementing the controllable semiconductor elements 221, 222 and the freewheeling elements 231, 232 as vertical devices, however, is only an example. Instead, the devices may also be implemented as so-called lateral devices. In lateral devices, all contact pads are arranged on a surface of the respective device that faces away from the respective substrate. If the controllable semiconductor elements 221, 222 and the freewheeling elements 231, 232 are implemented as lateral devices, the second contact pads of the two controllable semiconductor elements 221, 222 and the second contact pads of the two or more freewheeling elements 231, 232 may be electrically coupled to the first section 111₁ by means of one or more electrical connection elements 3. The first contact pad 21₁, 22₁, of each controllable semiconductor element 221, 222 of the two controllable semiconductor elements 221, 222 is electrically coupled to the first contact pad 31₁, 32₁, of one of the two freewheeling elements 231, 232, and to the second section 111₂ by means of one or more electrical connection elements 3. The third contact pads 21₃, 22₃, of the two controllable semiconductor elements 221, 222 are electrically coupled to each other by means of an electrical connection element 3. The third contact pad 22₃, of one of the two controllable semiconductor elements 221, 222 is further electrically coupled to the third section 111₃ by means of an electrical connection element 3. Further, the first contact pads 21₁, 22₁, of the two controllable semiconductor elements 221, 222 may be electrically coupled to each other by means of an electrical connection element 3.

The two controllable semiconductor elements 221, 222 as illustrated in FIG. 2 may form the first controllable semiconductor element T1, and the two freewheeling elements 231, 232 may form the first freewheeling element F1 of the half-bridge arrangement as illustrated in FIG. 3, or the two controllable semiconductor elements 221, 222 may form the second controllable semiconductor element T2, and the two freewheeling elements 231, 232 may form the second freewheeling element F2, for example. Two or more individual controllable semiconductor elements 22x (semiconductor bodies) may be electrically coupled in parallel to each other to form one element of a semiconductor arrangement, for example, in order to fulfill requirements concerning a current capability of the semiconductor arrangement. However, when controllable semiconductor elements that are electrically coupled in parallel are switched on and off, oscillations may occur. One type of oscillation that may occur are so-called inter-chip oscillations, where the parasitic capacitances of the controllable semiconductor elements oscillate against parasitic inductances that are present between the respective controllable semiconductor elements. Such oscillations may cause EMI (electromagnetic interference) problems, especially if frequencies in the double to triple digit MHz-range occur in the semiconductor arrangement. Such high frequency currents flow between the semiconductor bodies that are electrically coupled in parallel to each other. This may result in electrical tracks of a length of up to several centimeters which may act as antennas. On the other hand, high peak voltages and high currents may occur inside the controllable semiconductor elements 22x, which may eventually lead to a degradation of the gate oxide of the controllable semiconductor elements 22x, or even to defects and the melting of structures in the chip internal gate network.

Now referring to FIG. 4, a top view of a semiconductor module arrangement according to embodiments of the disclosure is schematically illustrated. In the semiconductor module arrangements according to embodiments of the disclosure, oscillations, and in particular inter-chip oscillations, are significantly reduced or even avoided. A semiconductor module arrangement according to embodiments of the disclosure includes a first substrate 10 comprising a dielectric insulation layer 11 and a first metallization layer 111 arranged on a surface of the dielectric insulation layer 11, wherein the first metallization layer 111 comprises a first section 111₁, a second section 111₂, a third section 111₃, and a fourth section 111₄. The semiconductor module arrangement further comprises two (or more) controllable semiconductor elements 221, 222, each controllable semiconductor element 221, 222 of the two (or more) controllable semiconductor elements 221, 222 comprising a first contact pad 21₁, 22₁, a second contact pad, and a third contact pad 21₃, 22₃, and one or more freewheeling elements 231, 232, each freewheeling element 231, 232 of the one or more freewheeling elements 231, 232 comprising a first contact pad 31₁, 32₁, and a second contact pad. The second contact pads of the two (or more) controllable semiconductor elements 221, 222 and the second contact pads of the one or more freewheeling elements 231, 232 are electrically coupled to the first section 111₁. In the example illustrated in FIG. 4, the second contact pads of the controllable semiconductor elements 221, 222 and the second contact pads of the freewheeling elements 231, 232 are electrically coupled to the first section 111₁ by means of electrically conductive connection layers (not visible in the top view illustrated in FIG. 4). As mentioned above, however, the second contact pads of the controllable semiconductor elements 221, 222 and the second contact pads of the freewheeling elements 231, 232 may instead be electrically coupled to the first section 111₁ by means of electrical connection elements 3 (e.g., if implemented as lateral devices). The first contact pad 21₁, 21₁ of each controllable semiconductor element 221, 222 of the two (or more) controllable semiconductor elements 221, 222 is electrically coupled to one or more first contact pads 31₁, 32₁, of the one or more freewheeling elements 231, 232 and to the second section 111₂ by means of one or more electrical connection elements 3. The third contact pad 21₃, 22₃, of each controllable semiconductor element 221, 222 of the two or more controllable semiconductor elements 221, 222 is electrically coupled to the third section 111₃ by means of one or more electrical connection elements 3, and the first contact pad 21₁, 22₁, of each controllable semiconductor element 221, 222 of the two (or more) controllable semiconductor elements 221, 222 is electrically coupled to the fourth section 111₄ by means of one or more electrical connection elements 3. In the example illustrated in FIG. 4, two freewheeling elements 231, 232 are exemplarily illustrated. However, in some applications only one freewheeling element may suffice. It is also possible that the semiconductor module arrangement comprises even more than two freewheeling elements.

As can be seen, the third contact pads 21₃, 22₃, of the controllable semiconductor elements 221, 222 of the arrangement illustrated in FIG. 4 are not directly coupled to each other by means of an electrical connection element 3, as has been described with respect to FIG. 2 above. Instead, each of the third contact pads 21₃, 22₃ is directly coupled to the third section 111₃ by means of one or more electrical connection elements 3. Further, the first metallization layer 111 comprises an additional fourth section 111₄, which is not present in the arrangement as illustrated in FIG. 2.

The fourth section 111₄ functions as an isolated path which is directly electrically coupled to each first contact pad 21₁, 21₁ of the two (or more) controllable semiconductor elements 221, 222. The fourth section 111₄ is not directly electrically coupled to any other components of the semiconductor module arrangement, or even to any other components outside the semiconductor module arrangement. The third section 111₃, for example, may be electrically coupled to the outside of the semiconductor module arrangement by means of one or more terminal elements 40. One such terminal element 40 is exemplarily illustrated in FIG. 4. No such terminal elements are arranged on and electrically coupled to the fourth section 111₄. The fourth section 111₄ only provides an additional path electrically coupling the first contact pads 21₁, 21₁ to each other. This additional path in combination with the emitter path in parallel results in a very low effective gate-loop inductance.

Similar to what has been described with respect to FIG. 2 above, the first contact pads 21₁, 22₁, of the two (or more) controllable semiconductor elements 221, 222 of the arrangement illustrated in FIG. 4 may additionally be electrically coupled to each other by means of one or more electrical connection elements 3. In this way, a second path which directly electrically couples the first contact pads 21₁, 21₁ to each other may be provided. This direct connection may further contribute in reducing unwanted oscillations.

Each of the two or more controllable semiconductor elements 22x may comprise a control electrode and a controllable load path between a first load electrode and a second load electrode. The load paths of the controllable semiconductor elements 22x are coupled in parallel to each other. The control electrode of a controllable semiconductor element 22x may be formed by or may be coupled to the third contact pad 2x₃ of the respective controllable semiconductor element 22x, the first load electrode may be formed by or may be coupled to the first contact pad 2x₁ of the respective controllable semiconductor element 22x, and the second load electrode may be formed by or may be coupled to the second contact pad of the respective controllable semiconductor element 22x. According to one example, the first contact pads 2x₁ of the one or more controllable semiconductor elements 22x are emitter pads, the second contact pads of the one or more controllable semiconductor elements 22x are collector pads, and the third contact pads 2x₃ of the one or more controllable semiconductor elements 22x are base (or gate) pads. According to an alternative example, the first contact pads 2x₁ of the one or more controllable semiconductor elements 22x are source or drain pads, the second contact pads of the one or more controllable semiconductor elements 22x are the respective other one of drain or source pads, and the third contact pads 2x₃ of the one or more controllable semiconductor elements 22x are gate pads.

Each of the one or more freewheeling elements 23x may include a first electrode and a second electrode. The first electrode of a freewheeling element 23x may be formed by or may be coupled to the first contact pad 3x₁ of the respective freewheeling element 23x, and the second electrode of a freewheeling element 23x may be formed by or may be coupled to the second contact pad of the respective freewheeling element 23x. The first contact pads 3x₁ of the two or more freewheeling elements 23x may be anode pads, and the second contact pads of the two or more freewheeling elements 23x may be cathode pads, for example, or vice versa.

Still referring to FIG. 4, for each controllable semiconductor element 221, 222 of the two (or more) controllable semiconductor elements 221, 222 the following may apply: the one or more electrical connection elements 3 electrically coupling the third contact pad 2x₃ to the third section 111₃ are arranged in parallel to the one or more electrical connection elements 3 electrically coupling the first contact pad 2x₁ to the fourth section 111₄. In this way, the base (or gate) and emitter paths (or source paths) of each controllable semiconductor element 22x electrically coupling the respective controllable semiconductor element 22x to the third section 111₃ and the fourth section 111₄, respectively, may be arranged closely adjacent to each other. With this, a strong inductive coupling between the two respective paths (on a substrate level) may be achieved. Both paths will drive effective emitter/source and gate/base inductances between the different controllable semiconductor elements 22x of the two or more controllable semiconductor elements 22x to a minimum value. At the same time, each controllable semiconductor element 22x of the two or more controllable semiconductor elements 22x will show the (essentially) same turn-on behavior (dI/dt) as compared to an arrangement as illustrated in FIG. 2, for example.

According to one example, a distance d3 between the one or more electrical connection elements 3 electrically coupling the third contact pad 2x₃ of a controllable semiconductor element 22x to the third section 111₃ and the one or more electrical connection elements 3 electrically coupling the first contact pad 2x₁ of the same controllable semiconductor element 22x to the fourth section 111₄ may equal a distance that is minimally required in order to provide sufficient insulation between the one or more electrical connection elements 3 electrically coupling the third contact pad 2x₃ to the third section 111₃ and the one or more electrical connection elements 3 electrically coupling the first contact pad 2x₁ to the fourth section 111₄. The minimally required distance between the respective electrical connection elements 3 may differ for different applications. The minimally required distance, for example, depends, inter alia, on the material that is used to form the electrical connection elements 3, on manufacturing processes that are used to assemble the arrangement, and on creepage distances. It further depends on the voltages occurring in the arrangement during its use. For example, the minimally required distance may be determined to comply with voltages of up to 40V. The minimally required distance generally is a distance between the one or more electrical connection elements 3 electrically coupling the third contact pad 2x₃ to the third section 111₃ and the one or more electrical connection elements 3 electrically coupling the first contact pad 2x₁ to the fourth section 111₄ at which no short-circuits or flashovers between the respective connection elements 3, which are connected to different electrical potentials, can occur.

In a second horizontal direction z, the fourth section 111₄ may be arranged between the first section 111₁ and the third section 111₃, and the first section 111₁ may be arranged between the fourth section 111₄ and the second section 111₂. That is, the fourth section 111₄ may be arranged closer to the third section 111₃ than the first section 111₁. The fourth section 111₄ being the section closest to the third section 111₃ further helps to reduce or even avoid the so-called inter-chip oscillations between the controllable semiconductor elements 22x coupled in parallel to each other. Arranging the fourth section 111₄ between the first section 111₁ and the third section 111₃, however, is only an example. It is, for example also possible, that the substrate is a so-called multi-layer substrate, i.e. a substrate comprising a first metallization layer 111 having a plurality of layers. In a multi-layer substrate, the third section 111₃, and the fourth section 111₄ may be arranged in the same horizontal plane or in different horizontal planes (e.g., vertically above each other).

According to one example, the fourth section 111₄ may be an elongated region. That is, a length of the fourth section 111₄ in a first horizontal direction x may be significantly larger than a width of the fourth section 111₄ in a second horizontal direction z, wherein the second horizontal direction z is perpendicular to the first horizontal direction x. The fourth section 111₄ may have an essentially rectangular shape. Any other shapes, however, are generally possible. A width of the fourth section 111₄ in the second horizontal direction z may be chosen to be large enough to provide sufficient space to attach the one or more electrical connection elements 3 thereto (e.g., to form reliable bonding connections). A length of the fourth section 111₄ in the first horizontal direction x generally depends on a size of and a distance between the controllable semiconductor elements 22x.

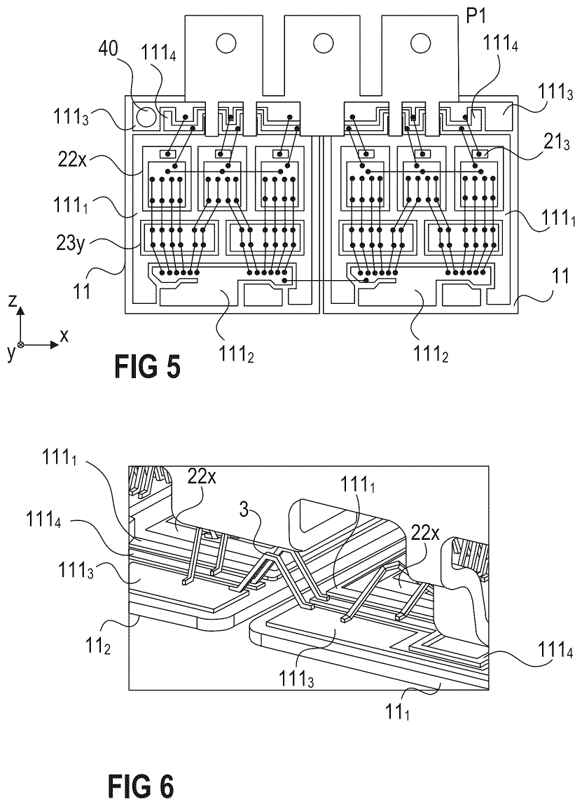

As is schematically illustrated in FIGS. 4 and 5, the fourth section 111₄ may have a meandering shape. That is, some sections of the fourth section 111₄ may be arranged closer to the controllable semiconductor elements 22x in the second horizontal direction z than other sections. A length of the electrical connection elements 3 connecting the third contact pad 2x₃ of each controllable semiconductor element 22x of the two or more controllable semiconductor elements 22x to the third section 111₃ may be chosen as short as possible. Therefore, the third section 111₃ may have sections that are arranged as close to the respective controllable semiconductor elements 22x (e.g., to the third contact pads 21₃, 22₃) as possible. However, as is schematically illustrated in FIGS. 4 and 5, the first section 111₁ may be electrically coupled to a first electrical potential P1 by means of a first bus bar, and the second section 111₂ may be electrically coupled to a second potential P2 that is different from the first potential P1 by means of a second bus bar. That is, a certain amount of space may have to be provided on the first section 111₁ in order to be able to connect the first bus bar thereto (e.g., by means of an electrically conduction connection layer). Bus bars are often arranged towards the edges of the substrate 10. Therefore, the first section 111₁ may have sections that are arranged further away from an edge of the substrate 10 (sections where the third section 111₃ is arranged as close as possible to the controllable semiconductor elements 22x) as well as sections that extend further towards the edge of the substrate 10 in order to provide sufficient space for attaching one or more bus bars thereto. This may result in the meandering shape of the fourth section 111₄ as illustrated in the figures. A meandering shape of the fourth section 111₄ may alternatively or additionally also result from slits created in the fourth section 111₄, for example. Such slits may be implemented, for example, in order to decrease the effective stray inductance of the arrangement.

FIG. 4 schematically illustrates one substrate 10 with two controllable semiconductor elements 22x and two freewheeling elements 23x attached thereto. As mentioned above, it is generally possible that more than two controllable semiconductor elements 22x and/or less (i.e. only one) or more than two freewheeling elements 23x are arranged on a substrate 10 in order to form the first controllable semiconductor element T1 and the first freewheeling element F1, or the second controllable semiconductor element T2 and the second freewheeling element F2 of a semiconductor arrangement (see, e.g., half-bridge arrangement of FIG. 3).

It is generally also possible that two or more of a plurality of controllable semiconductor elements 22x are arranged on a first substrate, and two or more of the plurality of semiconductor elements 22x are arranged on an additional second substrate 10. The same applies for the freewheeling elements 23x. This is schematically illustrated in FIG. 5. That is, in addition to the first substrate 10 described above with respect to FIG. 4, a semiconductor module arrangement may further comprise a second substrate 10 comprising a dielectric insulation layer 11 and a first metallization layer 111 arranged on a surface of the dielectric insulation layer 11, wherein the first metallization layer 111 comprises a first section 111₁, a second section 111₂, a third section 111₃, and a fourth section 111₄. The semiconductor module arrangement may further comprise two or more additional controllable semiconductor elements 22x, each additional controllable semiconductor element 22x of the two or more additional controllable semiconductor elements 22x comprising a first contact pad 2x₁, a second contact pad, and a third contact pad 2x₃, and one or more additional freewheeling elements 23x, each additional freewheeling element 23x of the one or more additional freewheeling elements 23x comprising a first contact pad 3x₁ and a second contact pad, wherein the second contact pads of the two or more additional controllable semiconductor elements 22x and the second contact pads of the two or more additional freewheeling elements 23x are electrically coupled to the first section 111₁ of the first metallization layer 111 of the second substrate 10. The first contact pad 2x₁ of each additional controllable semiconductor element 22x of the two or more additional controllable semiconductor elements 22x is electrically coupled to one or more first contact pads 3x₁ of the one or more additional freewheeling elements 23x and to the second section 111₂ of the second substrate 10 by means of one or more electrical connection elements 3. The third contact pad 2x₃ of each additional controllable semiconductor element 22x of the two or more additional controllable semiconductor elements 22x is electrically coupled to the third section 111₃ of the second substrate 10 by means of one or more electrical connection elements 3, and the first contact pad 2x₁ of each additional controllable semiconductor element 22x of the two or more additional controllable semiconductor elements 22x is electrically coupled to the fourth section 111₄ of the second substrate 10 by means of one or more electrical connection elements 3.

The first and second substrates 10 as illustrated in FIG. 5 are each essentially similar to the substrate 10 as illustrated in FIG. 4. However, in the example illustrated in FIG. 4, the number of controllable semiconductor elements 22x equals the number of freewheeling elements 23x on the substrate 10, which is not the case in the example illustrated in FIG. 5. In the example illustrated in FIG. 5, the number of controllable semiconductor elements 22x on each substrate 10 is greater than the number of freewheeling elements 23x on the same substrate 10. Each controllable semiconductor element 22x may be directly electrically coupled to only one of the freewheeling elements 23x on the same substrate 10 by means of one or more electrical connection elements 3, or to more than one of the freewheeling elements 23x on the same substrate 10.

Still referring to FIG. 5, the third section 111₃ of the first metallization layer 111 of the first substrate 10 may be electrically coupled to the third section 111₃ of the first metallization layer 111 of the second substrate 10 by means of one or more electrical connection elements 3. The fourth section 111₄ of the first metallization layer 111 of the first substrate 10 may be electrically coupled to the fourth section 111₄ of the first metallization layer 111 of the second substrate 10 by means of one or more electrical connection elements 3, and the second section 111₂ of the first metallization layer of the first substrate 10 may be electrically coupled to the second section 111₂ of the first metallization layer 111 of the second substrate 10 by means of one or more electrical connection elements 3. In this way, the controllable semiconductor elements 22x arranged on the first substrate 10 are coupled in parallel to the controllable semiconductor elements 22x arranged on the second substrate 10. The controllable semiconductor elements 22x arranged on the first substrate 10 and the controllable semiconductor elements 22x arranged on the second substrate 10 may together form the first controllable semiconductor element T1 as illustrated in FIG. 3, for example. Similarly, the freewheeling element(s) 23x arranged on the first substrate 10 and the freewheeling element(s) 23x arranged on the second substrate 10 may together form the first freewheeling element F1of the half-bridge arrangement as illustrated in FIG. 3. It is also possible, for example, that the controllable semiconductor elements 22x arranged on the first substrate 10 and the controllable semiconductor elements 22x arranged on the second substrate 10 together form the second controllable semiconductor element T2, and the freewheeling element(s) 23x arranged on the first substrate 10 and the freewheeling element(s) 23x arranged on the second substrate 10 together form the second freewheeling element F2 of the half-bridge arrangement as illustrated in FIG. 3.

FIG. 6 schematically illustrates electrical connection elements 3 electrically coupling the fourth section 111₄ of the first metallization layer 111 of the first substrate 10 to the fourth section 111₄ of the first metallization layer 111 of the second substrate 10, and electrically coupling the third section 111₃ of the first metallization layer 111 of the first substrate 10 to the third section 111₃ of the first metallization layer 111 of the second substrate 10 in further detail, as such connections are not visible behind the bus bar as illustrated in FIG. 5.

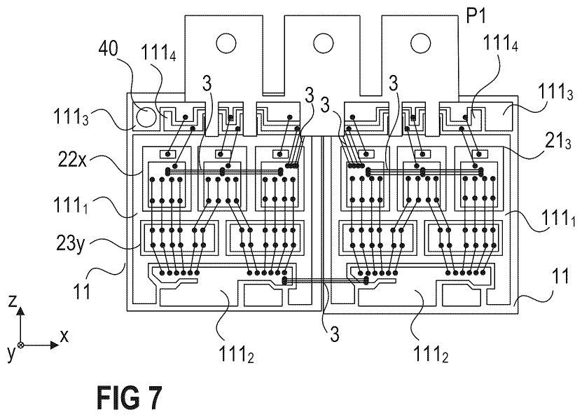

Generally, a single (only one/not more than one) electrical connection element 3 coupling a certain section of the first metallization layer 111 of the first substrate 10 to the respective section of the first metallization layer 111 of the second substrate 10 may be sufficient, as is schematically illustrated in FIGS. 5 and 6. However, a substrate-to-substrate connection may be further improved if more than one electrical connection 3 is used to form the respective substrate-to-substrate connections. This is schematically illustrated in FIG. 7. In the example illustrated in FIG. 7, the third section 111₃ of the first metallization layer 111 of the first substrate 10 is electrically coupled to the third section 111₃ of the first metallization layer 111 of the second substrate 10 by means of more than one (e.g., at least three) electrical connection elements 3 (not visible behind the bus bar), the fourth section 111₄ of the first metallization layer 111 of the first substrate 10 is electrically coupled to the fourth section 111₄ of the first metallization layer 111 of the second substrate 10 by means of more than one (e.g., at least three) electrical connection elements 3 (not visible behind the bus bar), and the second section 111₂ of the first metallization layer 111 of the first substrate 10 is electrically coupled to the second section 111₂ of the first metallization layer 111 of the second substrate 10 by means of more than one (e.g., at least three) electrical connection elements 3. In this way, a very low inductive substrate-to-substrate connection may be achieved, which reduces undesired oscillations even further.

In addition to or instead of the connections provided between different substrates 10 of a semiconductor module arrangement, it is also possible that connections provided on each of the respective substrates 10 be implemented by more than one electrical connection element 3. Still referring to FIG. 7, the first contact pad 2x₁ of at least one controllable semiconductor element 22x of the two or more controllable semiconductor elements 22x may be electrically coupled to the fourth section 111₄ by means of more than one (e.g., at least three) electrical connection elements 3. In the example illustrated in FIG. 7, only one controllable semiconductor element 22x of the two or more controllable semiconductor elements 22x on each substrate 10 is electrically coupled to the fourth section 111₄ by means of more than one electrical connection elements 3 (four electrical connection elements in FIG. 7). The remaining controllable semiconductor elements 22x of the two or more controllable semiconductor elements 22x on each substrate 10 are electrically coupled to the fourth section 111₄ of the respective substrate 10 by means of only one electrical connection elements 3. This, however, is only an example. It is generally possible that the first contact pads 2x₁ of two or more (e.g., of all) controllable semiconductor elements 22x of the two or more controllable semiconductor elements 22x on each substrate 10 are electrically coupled to the fourth section 111₄ of the respective substrate 10 by means of more than one electrical connection elements 3. Using more than one electrical connection element 3 (e.g., at least two or at least three) may further contribute in reducing unwanted oscillations.

By electrically coupling each controllable semiconductor element 22x separately to the third section 111₃ of the first metallization layer 111, by providing an additional fourth section 111₄ of the first metallization layer 111, and by further electrically coupling each controllable semiconductor element 22x separately to the fourth section 111₄, a low-inductive connection (e.g., emitter or source connection) is provided between the different controllable semiconductor elements 22x. If the electrical connection elements 3 connecting a controllable semiconductor element 22x to the third section 111₃ and the electrical connection elements 3 connecting the same controllable semiconductor element 22x to the fourth section 111₄ are arranged in parallel and as close as possible to each other (e.g., distance d3 of less than 3 mm, or less than 2mm), a strong inductive coupling between the different controllable semiconductor elements 22x may be achieved. By means of such measures, effective source/emitter and gate/base inductances may be driven to a minimum. In this way, inter-chip oscillations may be significantly reduced or even avoided. Very good results may be achieved, for example, for high-frequency pole paths for drain-source voltages V_{DS}=200V, and for low-frequency pole paths for all drain-source voltages.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor module arrangement, comprising:
a first substrate comprising a dielectric insulation layer and a first metallization layer arranged on a surface of the dielectric insulation layer, wherein the first metallization layer comprises a first section, a second section, a third section, and a fourth section;
two or more controllable semiconductor elements each comprising a first contact pad, a second contact pad, and a third contact pad,
wherein the second contact pad of each controllable semiconductor element of the two or more controllable semiconductor elements is electrically coupled to the first section,
wherein the first contact pad of each controllable semiconductor element of the two or more controllable semiconductor elements is electrically coupled to the second section by one or more electrical connection elements,
wherein the third contact pad of each controllable semiconductor element of the two or more controllable semiconductor elements is electrically coupled to the third section by one or more electrical connection elements, and
wherein the first contact pad of each controllable semiconductor element of the two or more controllable semiconductor elements is electrically coupled to the fourth section by one or more electrical connection elements.

2. The semiconductor module arrangement of claim 1, wherein in a second horizontal direction, the fourth section is arranged between the first section and the third section, and the first section is arranged between the fourth section and the second section.

3. The semiconductor module arrangement of claim 1, wherein the first contact pads of the two or more controllable semiconductor elements are electrically coupled to each other by one or more electrical connection elements.

4. The semiconductor module arrangement of claim 1, wherein for each controllable semiconductor element of the two or more controllable semiconductor elements:
the one or more electrical connection elements electrically coupling the third contact pad to the third section are arranged in parallel to the one or more electrical connection elements electrically coupling the first contact pad to the fourth section.

5. The semiconductor module arrangement of claim 4, wherein a distance between the one or more electrical connection elements electrically coupling the third contact pad to the third section and the one or more electrical connection elements electrically coupling the first contact pad to the fourth section equals a distance that is minimally required to provide sufficient insulation between the one or more electrical connection elements electrically coupling the third contact pad to the third section and the one or more electrical connection elements electrically coupling the first contact pad to the fourth section.

6. The semiconductor module arrangement of claim 1, wherein the first section is electrically coupled to a first electrical potential by a first bus bar and the second section is electrically coupled to a second potential that is different from the first potential by a second bus bar.

7. The semiconductor module arrangement of claim 1, wherein:
the first contact pads of the two or more controllable semiconductor elements are emitter pads, the second contact pads of the two or more controllable semiconductor elements are collector pads and the third contact pads of the one two more controllable semiconductor elements are base pads; or
the first contact pads of the two or more controllable semiconductor elements are source or drain pads, the second contact pads of the two or more controllable semiconductor elements are the respective other one of drain or source pads and the third contact pads of the two or more controllable semiconductor elements are gate pads.

8. The semiconductor module arrangement of claim 1, further comprising:
one or more freewheeling elements each comprising a first contact pad and a second contact pad,
wherein the second contact pad of freewheeling element of the one or more freewheeling elements is electrically coupled to the first section, and
wherein the first contact pad of each controllable semiconductor element of the two or more controllable semiconductor elements is electrically coupled to the first contact pad of at least one of the one or more freewheeling elements and to the second section.

9. The semiconductor module arrangement of claim 1, further comprising:
a second substrate comprising a dielectric insulation layer and a first metallization layer arranged on a surface of the dielectric insulation layer, wherein the first metallization layer comprises a first section, a second section, a third section, and a fourth section;
two or more additional controllable semiconductor elements each comprising a first contact pad, a second contact pad, and a third contact pad,
wherein the second contact pad of each additional controllable semiconductor element of the two or more controllable semiconductor elements is electrically coupled to the first section of the second substrate,
wherein the first contact pad of each additional controllable semiconductor element of the two or more additional controllable semiconductor elements is electrically coupled to a first contact pad of one or more freewheeling elements and to the second section of the second substrate by one or more electrical connection elements,
wherein the third contact pad of each additional controllable semiconductor element of the two or more additional controllable semiconductor elements is electrically coupled to the third section of the second substrate by one or more electrical connection elements, and
wherein the first contact pad of each additional controllable semiconductor element of the two or more additional controllable semiconductor elements is electrically coupled to the fourth section of the second substrate by one or more electrical connection elements.

10. The semiconductor module arrangement of claim 9, wherein:
the third section of the first metallization layer of the first substrate is electrically coupled to the third section of the first metallization layer of the second substrate by one or more electrical connection elements;
the fourth section of the first metallization layer of the first substrate is electrically coupled to the fourth section of the first metallization layer of the second substrate by one or more electrical connection elements; and
the second section of the first metallization layer of the first substrate is electrically coupled to the second section of the first metallization layer of the second substrate by one or more electrical connection elements.

11. The semiconductor module arrangement of claim 10, wherein the third section of the first metallization layer of the first substrate is electrically coupled to the third section of the first metallization layer of the second substrate by more than one electrical connection element.

12. The semiconductor module arrangement of claim 10, wherein the fourth section of the first metallization layer of the first substrate is electrically coupled to the fourth section of the first metallization layer of the second substrate by more than one electrical connection element.

13. The semiconductor module arrangement of claim 10, wherein the second section of the first metallization layer of the first substrate is electrically coupled to the second section of the first metallization layer of the second substrate by more than one electrical connection element.

14. The semiconductor module arrangement of claim 10, wherein:
the third section of the first metallization layer of the first substrate is electrically coupled to the third section of the first metallization layer of the second substrate by more than one electrical connection element;
the fourth section of the first metallization layer of the first substrate is electrically coupled to the fourth section of the first metallization layer of the second substrate by more than one electrical connection element; and
the second section of the first metallization layer of the first substrate is electrically coupled to the second section of the first metallization layer of the second substrate by more than one electrical connection element.

15. The semiconductor module arrangement of claim 1, wherein the first contact pad of at least one controllable semiconductor element of the two or more controllable semiconductor elements is electrically coupled to the fourth section by more than one electrical connection element.
